(19) United States
(12) Patent Application Publication
(10) Pub. No.: US 2004/0209191 A1
(43) Pub. Date: Oct. 21, 2004

(54) Method for producing conductive structures by means of printing technique, and active components produced therefrom for integrated circuits

(76) Inventors: Adolf Bernds, Baiersdorf (DE); Wolfgang Clemens, Puschendorf (DE); Walter Fix, Nurnberg (DE); Alexander Friedrich Knobloch, Neunkirchen (DE); Andreas Ullmann, Furth (DE)

Correspondence Address: YOUNG & THOMPSON, 745 SOUTH 23RD STREET 2ND FLOOR, ARLINGTON, VA, 22202

(21) Appl. No.: 10/479,238

(22) PCT Filed: May 13, 2002
(86) PCT No.: PCT/DE02/01717

(30) Foreign Application Priority Data
Jun. 1, 2001 (DE) 101 26 859.9

(51) Int. Cl. G03F 7/00

(52) U.S. Cl. 430/311

(57) ABSTRACT

The invention relates to a method for producing conductive structures. Said method is characterized in that strip conductors or electrodes are directly or indirectly produced in a conductive layer by means of a printing technique. The inventive method is especially suitable for producing electrodes and strip conductors in simple, fast and cost-effective ways.

A method for producing conductive structures by means of a printing technique as well as active components produced thereof for integrated circuits.

The invention relates to a method for producing conductive structures as well as active components produced thereof, in particular, organic field-effect transistors (OFETs), organic light-emitting diodes (OLEDs) or integrated circuits comprised thereof.

Conductive and finely structured electrodes or strip conductors, which can be produced from conductive materials such as metals, organically conductive polymers or polymers filled with particles, are required to realize organic or inorganic optoelectronic components. Hereby, organic layers can be structured photochemically (see C. J. Drury et al., Applied Physics Letter 73 (1) (1998) 108 and G. H. Gelink et al., Applied Physics Letter 77 (10) 2000, 1,487), or by means of lithography (synthetic method 101 (1999) 705). Similar methods are also possible to structure inorganic conductive layers).

Said methods for structuring conductive layers or generating strip conductors or electrodes are very complex in terms of working techniques and thus very time-consuming and costly. Therefore, these processes are too extensive, in particular, for producing high-resolution conductive structures in optoelectronic components, such as OFETs, OLEDs and the like.

The applicant's [patent] DE 10047171.4, which has not yet been published, describes a method for producing an electrode and/or a strip conductor comprised of organic material through contact with a chemical compound. Organic

materials have a disadvantage in that they are not as stable as corresponding inorganic materials.

It is therefore the purpose of the present invention to specify a method enabling the production of high-resolution conductive structures comprised of inorganic material, if possible, in a simple and cost-effective process and with as few procedures as possible.

Therefore, the object of the present invention is a method for producing conductive layers characterized in that strip conductors or electrodes are produced in a conductive layer by means of a printing technique.

The method is rendered substantially simpler, cheaper and quicker due to printable structuring. In addition, all procedures, which are required, for example, for lithography, such as the application of photosensitive resist, light exposure, development and subsequent cleaning, if applicable, can be omitted.

In principal, all printing methods, such as gravure, letterpress, planographic and through printing (screen printing) are suitable. However, a particularly preferred embodiment according to the present invention is the production of strip conductors or electrodes by means of the so-called offset gravure printing method. This is called tampon printing. The advantage of this printing method is characterized in that the structure to be generated can be connected positively or negatively in the shape of a printing plate that contains the printing paste.

It is the advantage of the method according to the present invention that it is suitable for producing organic as well as inorganic conductive structures or strip conductors or electrodes.

A preferred conductive organic layer, for example, is doped polyaniline, in which a non-conducting matrix is produced through printing with an alkaline print medium using deprotonation.

A conductive structure in a non-conducting matrix can also be produced by printing non-doped polyaniline with an acidic print medium by means of protonation. Said matrix can then be removed and, if appropriate, filled in with a semiconducting layer. For reasons of stability of the optoelectronic component, which contains a conductive, structured layer produced in accordance with the present invention, it is advantageous to choose said layer from inorganic conductive material, preferably gold, aluminum, copper or indium tin oxide (ITO). At first, a metallic conductive layer, which, for example, can be between 1 and 100 nm thick, is applied by vacuum deposition, for example, on a substrate or a lower layer. Then, a suitable, negative resist paste is printed on the strip conductor or electrode to be produced by means of the offset gravure printing method, whereby the conductive layer in the printed areas is etched away by forming strip conductors or electrodes. Also, a resist paste, which is removed after the etching process, can be printed inversely positive.

Said paste may have alkaline or acidic characteristics, depending on the conductive layer to be produced.

It is advantageous that the method according to the invention is developed in a continuous fashion, which guarantees mass production.

The invention also concerns an organic field-effect transistor, whereby source, drain and/or gate electrodes are produced according to the method of the present invention.

The invention also concerns organic light-emitting diodes, whereby conductive structures are formed in accordance with the method of the present invention.

The invention also concerns organic diodes, in particular, rectifier diodes.

The invention also concerns integrated circuits comprising at least one OFET or another active component, said component being produced in accordance with the method of the present invention.

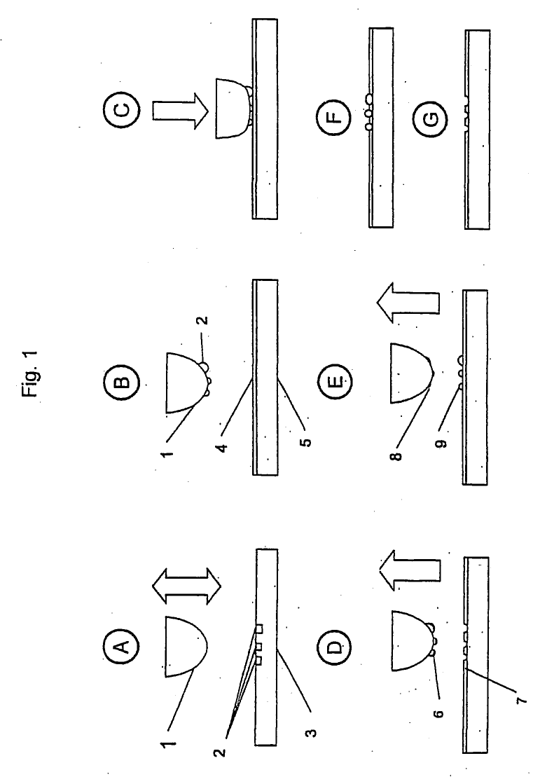

Below, the invention is described in detail using an embodiment example and the enclosed FIG. 1.

During step A, a high-viscosity printing paste 2 is removed from the printing plate 3 by means of a rubber stamp 1. Preferably, said rubber stamp 1 consists of a material resistant to the reactive printing paste 2. In order to form inorganic strip conductors or electrodes, silicone is most suitable due to its resistance to swelling and acid. Said printing plate 3 contains said printing paste as a negative printing plate of the strip conductors or electrodes to be produced. During steps B and C, said printing paste 2 is applied by means of said rubber stamp 1, to a substrate 5, which is coated with a conductive layer 4. Said printing paste 2 adheres to said rubber stamp 1 in the shape of discrete structures, enabling said conductive layer 4 to be treated for structuring. In the specified embodiment, said conductive layer 4 is comprised of a conductive metallic layer between 1 and 100 nm, such as, for example, gold, aluminum, copper or ITO, which had been vacuum-deposited. Said printing paste 2 comprises corrosive characteristics, exhibiting a content of ferric chloride in the case of the application with copper, a content of iodine/potassium iodide in the case of the application with gold, a content of haloid acid in the case of the application with ITO, and a content of hydrochloric acid or sodium hydroxide in the case of the application with aluminum.

In principal, the substrate can be chosen freely and may therefore be a silicon carrier or a thin layer of glass. Preferably, however, very thin flexible plastic films made of, for example,

polyethylene, polyethylene terephthalate or polyimide will be used. Said conductive layer 4 does also not have to be deposited directly on said carrier substrate 5. The layer beneath can also be a partially finished, optoelectronic component, which already displays structured functional layers.

In principal, there are two different processing steps depending on the characteristics of the used printing paste, which will be explained below:

According to step D, said printing paste is characterized in that a conductive inorganic layer 6, according to the printing structure, adheres to the adhesive print medium and can therefore be directly removed from the substrate. This process can be repeated several times, if need be, provided that said removed conductive layer 6 dissolves in said print medium, in each case. Conductive structure 7 remains, which can be processed, for example, to build up an OFET or another optoelectronic component. Using this method, said rubber stamp 1, also called tampon, must be cleaned afterwards in order to repeat said process step. Said process can be performed by means of an intermediate step, which will not be detailed here, in which said rubber stamp 1 is immersed into a suitable solvent.

According to another embodiment or by means of a different print medium, said printing paste 3 is directly transferred to said conductive layer 4 (Step E). A structured printing paste 9 and said conductive layer 4 react with one another and said conductive layer 4 is detached from said stamp 1 in the areas containing the prints (Step F). Remaining residue 8 at said stamp 1 must be removed. In order to avoid high lateral corrosion, the process must be stopped through neutralization in a base, without said base reacting with said conductive layer. Step G demonstrates how the structure, after neutralization and removal,

is formed in said conductive layer. Here, too, additional processing steps, as described hereinabove, may follow.

1. A method for producing conductive structures, characterized in that strip conductors and/or electrodes can be directly or indirectly produced inside said conductive layer (4) by means of a printing technique.

2. A method in accordance with claim 1, characterized in that strip conductors and/or electrodes can be produced using the offset gravure printing method by applying said reactive printing paste (3).

3. A method in accordance with claim 1 or 2, characterized in that an organic conductive layer is produced and structured by means of the offset gravure printing method.

4. A method in accordance with claim 4, characterized in that the conductive organic layer is doped polyaniline, in which a non-conducting matrix is produced through printing with an alkaline medium using deprotonation.

5. A method in accordance with claim 4, characterized in that the conductive organic layer is non-doped polyaniline, in which a non-conducting matrix is produced through printing with an acid medium using deprotonation.

6. A method in accordance with claim 1 or 2, characterized in that said inorganic conductive layer is produced.

7. A method in accordance with claim 6, characterized in that said conductive inorganic layer from [missing text]

8. A method in accordance with claims 1 through 7, characterized in that said printing process is performed continuously.

9. An organic field-effect transistor, whereby source, drain and/or gate electrodes are formed using a method in accordance with claims 1 through 8.

10. A light-emitting electrode, whereby conductive structures are formed using a method in accordance with claims 1 through 8.

11. An organic (rectifier) diode, whereby conductive structures are formed using a method in accordance with claims 1 through 8.

12. Integrated circuits comprising at least one active component in accordance with one of claims 9 through 11.
